(19) United States
(12) Patent Application Publication
(10) Pub. No.: US 2010/0115181 A1
(43) Pub. Date: May 6, 2010

(54) MEMORY DEVICE AND METHOD

(75) Inventor: Magnus Tillgren, Malmo (SE)

Correspondence Address: HARRITY & HARRITY, LLP, 11350 RANDOM HILLS ROAD, SUITE 600, FAIRFAX, VA, 22030, US

(73) Assignee: Sony Ericsson Mobile Communications AB, Lund (SE)

(21) Appl. No.: 12/264,321

(22) Filed: Nov. 4, 2008

(51) Int. Cl. G06F 12/00; H01L 27/24; G06F 13/14; G06F 12/02

(52) U.S. Cl. 711/103; 710/305; 438/128; 257/E27.004; 711/E12.001; 711/E12.008

(57) ABSTRACT

A memory device may include a volatile memory and a non-volatile memory which are arranged to be accessed via a common bus. The memory device may include a controller that is arranged as an interface between the common bus and the volatile and non-volatile computer memories, the controller to transmit read/write commands from the common bus to either the volatile memory or the non-volatile memory.

### TECHNICAL FIELD

The present invention generally relates to a memory device and a device including a memory device and, more particularly, a method for fabricating a memory device and a method for accessing a volatile memory and/or a non-volatile memory of a memory device.

### BACKGROUND

Memory devices used in relatively compact data terminals, such as mobile telephones, typically include a non-volatile memory for storing instruction codes of a central processing unit (CPU) and various data that has to be retained when the power is turned off and a volatile memory for temporarily storing data, which is lost when the power is turned off.

Flash memory is a commonly used non-volatile computer memory that can be electrically erased and reprogrammed. It is a specific type of Electrically Erasable Programmable Read-Only Memory (EEPROM) that is erased and programmed in large blocks. No power is needed to maintain the information stored in a flash memory chip. In addition, flash memory offers fast read access times. Another feature of flash memory is that, when packaged in a memory card, it is extremely durable, being able to withstand intense pressure, temperature extremes, and even immersion in water.

Flash memory may be of the NAND or NOR type. NAND flash memory may have faster erase and write times, and require a smaller chip area per cell, thus allowing greater storage densities and lower costs per bit than NOR flash memory. NAND flash memory may have up to ten times the endurance of NOR flash memory. However, the I/O interface of NAND flash memory does not provide a random-access external address bus. Rather, data is read on a block-wise basis, with typical block sizes of hundreds to thousands of bits.

Synchronous dynamic random access memory (SDRAM) is a commonly used volatile computer memory. SDRAM has a synchronous interface, meaning that it waits for a clock signal before responding to control inputs and is therefore synchronized with the computer's system bus. The clock is used to drive an internal finite state machine that pipelines incoming instructions. This allows the chip to have a more complex pattern of operation than asynchronous dynamic random access memory (DRAM), which does not have a synchronized interface. Pipelining refers to the chip accepting a new instruction before it has finished processing a previous instruction. In a pipelined write, the write command can be immediately followed by another instruction without waiting for the data to be written to the memory array. In a pipelined read, the requested data appears after a fixed number of clock pulses after the read instruction, cycles during which additional instructions can be sent.

A disadvantage with memory devices using a volatile memory and a non-volatile memory is that both types of memories require separate interfaces, which significantly increases the number of interface lines, i.e., the number of buses and pins required. This increases space-requirements, which can be a significant problem in small-sized data terminals, such as mobile phones, where space is at a premium.

European Patent Application No. EP 1 796 100 A2 relates to a memory device that includes a volatile memory and a flash memory. The memory device includes a single internal bus for communicating with a host using only a volatile memory protocol. A controller is provided between the volatile memory and the internal bus to exchange code with the host and to exchange signals directly between the internal bus and the volatile memory. Since both the volatile memory and the non-volatile memory are connected via a single internal bus, there will, however, be an increased load on the bus, which may adversely affect the performance of the bus and consequently the performance of the memory device.

### SUMMARY

Embodiments of the invention overcome or at least ameliorate one or more of the above disadvantages and/or provide a viable alternative solution using an improved memory device.

Embodiments of the invention provide a memory device including a volatile memory and a non-volatile memory which may be arranged to be accessed via a common bus, i.e., data may be arranged to be written to, and/or read from the memories by sending signals via only one bus. The memory device may include a controller that is arranged as an interface between the common bus and the volatile and non-volatile computer memories, the controller being arranged to transmit read/write commands, i.e., commands/signals/data etc., from the common bus to either the volatile memory or the non-volatile memory.

Such a memory device may provide a common interface for both a volatile memory and a non-volatile memory including only one bus between a CPU, from/to which read/write commands/signals are sent, and the two memories. All read/write commands/signals from the CPU may be sent via the common bus, and the controller may then send the read/write commands/signals to the memory for which they are intended. This may be controlled, for example, by chip select signals.

It should be noted that the expressions, “volatile memory” and “non-volatile memory” of a memory device, according to any of the embodiments of the invention, are intended to include cases in which a particular memory includes just one type of memory or a plurality of memories of that type. For example a non-volatile memory may include a NAND flash memory only, a NOR flash memory only, or both a NAND flash memory and a NOR flash memory.

The expression “bus” of a memory device, according to any of the embodiments of the invention, is intended to include one or more electrical conductors that form(s) a transmission path.

According to an embodiment of the invention, the volatile memory may include SDRAM memory, i.e., any type of synchronous dynamic RAM.

According to another embodiment of the invention, the common bus may include a RAM bus, for example, a double data rate (DDR) bus.

According to a further embodiment of the invention, the controller may be arranged to receive read/write commands/signals including an address to either the volatile memory or the non-volatile memory. Alternatively, or additionally, the controller may be arranged to recognize whether a read/write command/signal is to be transmitted to the volatile memory or the non-volatile memory.

According to an embodiment of the invention, the memory device may include a cache that may be used to temporarily store read/write commands/signals that are to be transmitted to the non-volatile memory, so that the common bus will not be occupied by waiting for NAND-specific operations, for example. The cache may either be a separate unit or a part of the volatile memory. A part of a SDRAM memory may, for example, be used as a cache to reduce manufacturing costs.

According to another embodiment of the invention, the controller may be arranged to carry out error correction code (ECC) operations and/or wear levelling to minimize bus traffic.

According to a further embodiment of the invention, the controller may be arranged to transfer data (including page-on-demand pages) between the volatile memory and the non-volatile memory so that the data does not preoccupy the bus.

According to an embodiment of the invention, the volatile memory and the non-volatile memory and the controller may be fabricated on a common die. These components may alternatively be fabricated on a plurality of dies.

The present invention relates to a device, for instance a portable device, such as a mobile telephone, media player, personal communications system (PCS) terminal, personal data assistant (PDA), laptop computer, palmtop receiver, camera or television, which includes a memory device according to any of the embodiments of the invention.

The present invention relates to a method for fabricating a memory device memory including a volatile memory and a non-volatile memory. The method may include the steps of providing at least one die and fabricating the volatile memory, the non-volatile memory, and a controller as an interface to the volatile and non-volatile computer memories on the at least one die, the controller being arranged to transmit read/write commands and/or any other signals to either the volatile memory or the non-volatile memory. Such a method may be used to fabricate a memory device according to any of the embodiments of the invention.

The present invention relates to a method for accessing a volatile memory and/or a non-volatile memory. The method may include the steps of: transmitting a read/write command and/or any other signal via a bus that is common to the volatile memory and the non-volatile memory, and subsequently transmitting the read/write command to either the volatile memory or the non-volatile memory via a controller that constitutes an interface between the common bus and the volatile and non-volatile computer memories.

### BRIEF DESCRIPTION OF THE DRAWINGS

The present invention will hereinafter be further explained by means of non-limiting examples with reference to the appended schematic figures.

FIG. 1 shows components of a memory device;

FIG. 2 shows an exemplary memory device according to an embodiment of the invention; and

FIGS. 3 and 4 are flow charts showing the steps of methods according to embodiments of the invention.

It should be noted that the drawings have not been drawn to scale and that the dimensions of certain features may have been exaggerated for purposes of clarity.

### DETAILED DESCRIPTION OF EMBODIMENTS

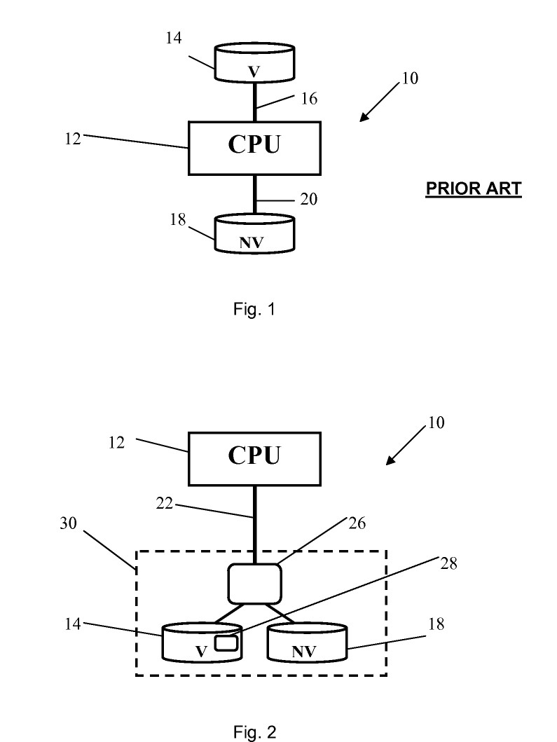

FIG. 1 shows a conventional memory device 10. Memory device 10 includes a CPU 12 connected to a volatile memory 14 via a first bus 16 and connected to a non-volatile memory 18 via a second bus 20. Because more than one bus is provided, memory device 10 may have to have a relatively large number of pins and/or leads (not shown) for establishing electrical contact between the various components of memory device 10, thereby increasing the overall minimum dimensions of memory device 10.

FIG. 2 shows exemplary memory device 10 according to an embodiment of the invention. Memory device 10 may include a volatile memory 14, such as a SDRAM, DDR SDRAM, or QDR (quadruple data rate) SDRAM memory or a derivative thereof, and a non-volatile memory 18, such as a NAND or a NOR flash memory. Non-volatile memory 18 may be used to store programs and data such as image, video, audio, and/or data files, for example. Data may be read and/or written from/to either volatile memory 14 and/or non-volatile memory 18 in accordance with, for example, commands from CPU 12.

Both volatile memory 14 and non-volatile memory 18 may be configured to be accessed via a common bus 22, such as a DDR bus. Memory device 10 may include a controller 26 that may be configured as an interface between common bus 22 and volatile memory 14 and non-volatile memory 18. Controller 26 may be configured to transmit signals, such as read/write commands and/or data, from common bus 22 to volatile memory 14 and/or non-volatile memory 18 and/or signals from volatile memory 14 and/or non-volatile memory 18 to common bus 22. Controller 26 and CPU 12 may be configured to communicate using a plurality of different protocols, or just one protocol.

Controller 26 may be configured to receive signals including an address. Non-volatile memory 18 may, for example, include an array of cells configured in a plurality of addressable banks, where each memory bank contains addressable sectors of memory cells. The data stored in non-volatile memory 18 may then be accessed using externally provided location addresses. The addresses may be decoded using row address decoder circuitry and/or bank control logic. To access an appropriate column of the memory, the received addresses may be coupled to column decode circuitry. Command execution logic may be provided to control the basic operations of memory device 10, such as read, write, erase, and/or other memory operations.

Alternatively, or additionally, controller 26 may be configured to recognize whether a signal from CPU 12 is to be transmitted to volatile memory 14 and/or non-volatile memory 18. Controller 26 may be configured to carry out error correction code (ECC) operations and/or wear levelling and/or to transfer data between volatile memory 14 and non-volatile memory 18.

It should be noted that read/write commands/signals intended for both volatile memory 14 and non-volatile memory 18 may be combined and sent at the same time to controller 26 via bus 22. Controller 26 may be configured to ensure that each read/write command/signal is sent to the memory for which it is intended.

Memory device 10 illustrated in FIG. 2 may include a cache 28 that may be used to temporarily store read/write commands that are to be transmitted to non-volatile memory 18. Controller 26 may use a portion of volatile memory 14 as cache 28 as shown in the illustrated embodiment, and/or cache 28 may be an integral and/or separate part of controller 26. Furthermore, volatile memory 14, non-volatile memory 18, and/or controller 26 may be fabricated on a common die 30, i.e., in a single chip, using any suitable integrated circuit technique(s). The components of memory device 10 according to the present invention may, however, be fabricated on a plurality of dies.

It should be noted that volatile memory 14 and non-volatile memory 18 of memory device 10, according to the present invention, need not necessarily be spatially separated as shown in FIG. 2, a single memory package may, for example, include one or more volatile memory parts and one or more non-volatile memory parts.

When CPU 12 writes to non-volatile memory 18, data may be sent to controller 26 that in turn (quickly) writes to cache 28 and/or to a select portion of volatile memory 14. Controller 26 may begin writing to non-volatile memory 18. During this time, CPU 12 can write to, and/or read volatile memory 14 unhindered, for example, by other processing in memory device 10. When the writing to non-volatile memory 18 has been completed, controller 26 may be configured to send a “ready” signal to CPU 12.

When CPU 12 reads from non-volatile memory 18, a read command may be sent to controller 26 that in turn begins to read non-volatile memory 18 and save the data in cache 28 or a select portion of volatile memory 14. During this time, CPU 12 can write to and/or read from volatile memory 14 un-hindered, for example, by other processing in memory device 10. When non-volatile memory 18 has been read, controller 26 may be configured to send a “ready” signal to CPU 12. CPU 12 may namely be configured to read data from non-volatile memory 18 via cache 28.

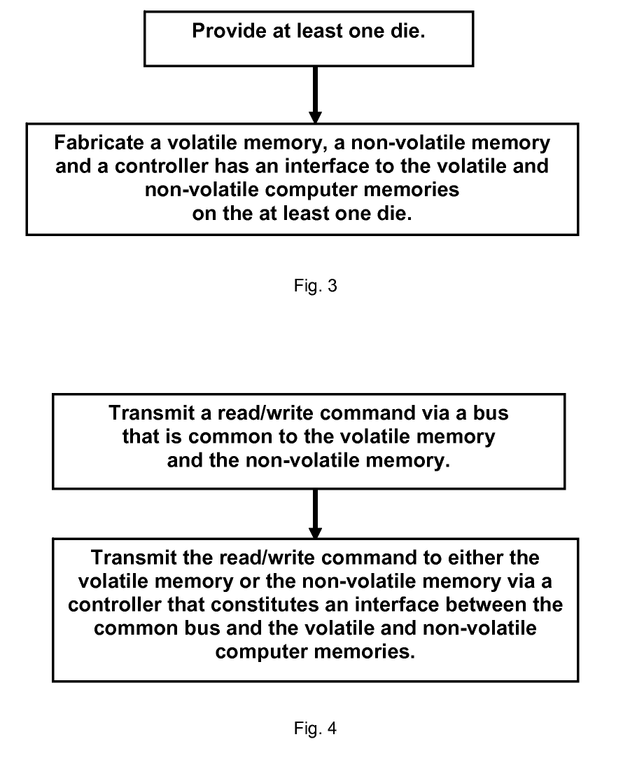

FIG. 3 shows the steps of a method of forming a memory device, according to any of the embodiments of the invention. The method may include the steps of providing at least one die and fabricating volatile memory 14, non-volatile memory 18, and controller 26 as an interface to volatile memory 14 and non-volatile memory 18 on the at least one die, in which controller 26 may be configured to transmit read/write commands and/or other signals and/or data to either volatile memory 14 and/or non-volatile memory 18.

FIG. 4 shows the steps of a method for accessing a volatile memory and/or a non-volatile memory. The method may include the steps of providing memory device 10; transmitting a read/write command/signal via bus 22 that is common to volatile memory 14 and non-volatile memory 18; and transmitting the read/write command/signal to either volatile memory 14 and/or non-volatile memory 18 via controller 26 that operates as an interface between common bus 22 and volatile and non-volatile computer memories 14 and 18.

Further modifications of the invention within the scope of the claims would be apparent to a skilled person. For example, even though the claims recite a volatile memory and a non-volatile memory, the present invention is applicable to a memory device that includes any two types of memory, e.g., a first memory and a second memory, not necessarily a volatile memory and a non-volatile memory. The memory device may include any number of types of memory, e.g., three, four, five, or more, where two, three, or more of the memories are connected by a single bus. For example, the memory device may advantageously include two memories connected by a single bus, and three other (different) memories connected by another, different single bus, or any other number of combinations of memories and common busses. The memory device may take any form, for example, a field programmable gate array, an application specific integrated circuit, etc.

It should also be noted that the feature(s) in any claim that is dependent on a particular claim may be combined with the feature(s) in one or more other claims that is/are also dependent on that particular claim unless the features of two dependent claims explicitly exclude such a combination.

What is claimed is:

1. A memory device comprising:
a volatile memory;
a non-volatile memory;
a bus common to the volatile memory and the non-volatile memory; and
a controller configured as an interface between the bus and the volatile memory and the non-volatile memory, said controller to transmit read and/or write commands received via the bus to at least one of the volatile memory or the non-volatile memory.

2. The memory device of claim 1, where the non-volatile memory is a NAND flash memory.

3. The memory device of claim 1, where the non-volatile memory is a NOR flash memory.

4. The memory device of claim 1, where the volatile memory is a synchronous dynamic random access memory (SDRAM).

5. The memory device of claim 1, where the bus is a random access memory (RAM) bus.

6. The memory device of claim 5, where the bus is a double data rate (DDR) bus.

7. The memory device of claim 1, where the read/write commands comprise an address to at least one of the volatile memory or the non-volatile memory.

8. The memory device of claim 1, where the controller is to recognize whether a read/write command is to be transmitted to the volatile memory or the non-volatile memory.

9. The memory device of claim 1, further comprising:
a cache to temporarily store the read/write commands to be transmitted to the non-volatile memory.

10. The memory device of claim 1, where the controller is to carry out error correction code (ECC) operations and/or wear levelling.

11. The memory device of claim 1, where the controller is to direct transfer data between the volatile memory and the non-volatile memory.

12. The memory device of claim 1, where the volatile memory and the non-volatile memory and the controller reside on a common die.

13. The memory device of claim 1, further comprising:
a central processing unit connected to the controller via the bus.

14. A communications device comprising:
a memory device including:
a volatile memory,
a non-volatile memory,
a bus common to the volatile memory and the non-volatile memory, and
a controller configured as an interface between the bus and the volatile memory and the non-volatile memory, said controller to transmit read and/or write commands received via the bus to at least one of the volatile memory or the non-volatile memory.

15. The communications device of claim 14, where communications device comprises a mobile telephone, a media player, a personal communications system (PCS) terminal, a personal data assistant (PDA), a laptop computer, a palmtop receiver, a camera, or a television.

16. A method for fabricating a memory device including a volatile memory and a non-volatile memory, the method comprising:
providing at least one die; and
fabricating, on the at least one die, a volatile memory, a non-volatile memory, and a controller as an interface to the volatile memory and the non-volatile memory and being configured to transmit read/write commands to at least one of the volatile memory or the non-volatile memory.

17. A method of accessing a volatile memory and a non-volatile memory, the method comprising:
transmitting a read/write command via a bus common to the volatile memory and the non-volatile memory; and
transmitting the read/write command to at least one of the volatile memory or the non-volatile memory via a controller configured as an interface between the bus and the volatile memory and the non-volatile memory.
